(19) United States
(12) Patent Application Publication
(10) Pub. No.: US 2014/0338721 A1
(43) Pub. Date: Nov. 20, 2014

(54) PHOTOVOLTAIC TEXTILES

(71) Applicants: Donald G. Parent, Windham, ME (US); Mustafa G. Guvench, Falmouth, ME (US)

(72) Inventors: Donald G. Parent, Windham, ME (US); Mustafa G. Guvench, Falmouth, ME (US)

(21) Appl. No.: 14/344,565

(22) PCT Filed: Sep. 12, 2012
(86) PCT No.: PCT/US12/54866

§ 371 Date: Mar. 12, 2014

(51) Int. Cl. H02S 30/20; H01L 31/02

(52) U.S. Cl. CPC H01L 31/045; H01L 31/0201
USPC 136/245; 136/256

(57) ABSTRACT

Textile systems and components for establishing electrical characteristics of textiles. The textiles incorporate charge carrying components, such as photovoltaic components, in contact with highly conductive bus conduits to improve electrical properties without compromising physical characteristics of the textiles. Structure, geometries, and methods are provided for textile constructs, including photovoltaic textile constructs.

### BACKGROUND OF THE INVENTION

1. Field of the Invention

This invention relates to textiles designed for converting electrical charges, such as charges generated through solar energy, into usable electricity. More specifically the invention is directed to electrical charge transfer textiles, photovoltaic systems, solar textiles, and sub-components which reduce electrical resistance for improved performance.

2. Description of Related Art

Photovoltaic systems convert sunlight into electricity through the action of photovoltaic cells. Large solar arrays currently in use typically have numerous panels or modules, each with many photovoltaic cells. Such arrays have been made from rigid components. More recently, flexible photovoltaic components have been developed that may be incorporated into textiles as alternatives to rigid cells and modules.

Flexible solar energy technology holds great promise for many applications. The freedom of movement provided by fabrics has the potential for making solar energy conversion structures that are more easily transported and erected than comparable rigid solar structures. Such systems could be used to bring much needed electricity to remote or disaster ridden areas that would otherwise be without power. In other applications, efficient solar textiles integrated into common fabric articles such as hats, garments, tents, and coverings could potentially provide electric power on a smaller scale.

Small cross-section photovoltaic fibers used for solar textile applications provide uniformity and fabric-like flexibility. Inexpensive and flexible polymer photovoltaics (PPVs) are well suited for use as fibers. However, attempts at producing efficient solar textiles from existing PPV components have been constrained by fundamental technical barriers relating to their inherent electrical resistance.

Present PPV fibers of coaxial construction rely on a centered inner conductor and a transparent external conductor, such as ITO (Indium Tin Oxide) or a conducting polymer such as PEDOT (Poly(3,4-ethylenedioxythiophene) poly(styrenesulfonate)), to move charge along the fiber. However, when such fibers are incorporated into a textile, the low electrical conductivity of the external, optically transparent electrode causes significant voltage drop in the available electricity. The voltage drop results because the transparent electrode provides two critical but contradictory functions. The first function is to pass solar flux unimpeded through the transparent electrode into the optically active photoelectric layers beneath the surface. The second function is to move or transport electric charge axially along the sheet dimension of the transparent electrode with minimum voltage drop or loss. Efficient optical transmission requires maximum optical clarity, implying a relatively thin electrode. However, efficient charge transport requires sufficient thickness to provide a low electrical resistance path. While one function optimizes with increasing thickness the other optimizes with decreasing thickness. Currently available optically transparent compounds, such as ITO and many of the new polymer-based substances such as PEDOT, do not simultaneously satisfy the optical clarity and electrical conductivity requirements. For PPV components made from these substances, acceptable optical transmission results in excessive electrical sheet resistance for use in solar textiles.

Other photovoltaic fiber designs rely on dual internal conductors throughout their length. However, the movement of power through textiles made from such fibers is generally more complicated and less reliable because of the need to make and maintain additional electrical connections with external circuitry. Furthermore, the small cross sectional dimension typical of internal conductors restricts charge flow. Similar to co-axial fibers, charge transport along the axis of dual internal conductor fibers yields large voltage drop, thereby diminishing the performance of textiles in which such fibers are used.

Attempts at producing photovoltaic (PV) fibers for textiles have reported power conversion efficiencies of only 0.01% with electrical fill factors of 24%. (A Photovoltaic Fiber Design for Smart Textiles, Textile Research Journal, Vol. 80(11): 1065-1074 DOI. It has also been reported that: “An n-type carrier counter electrode that is both highly conductive and optically transparent has not been reported. Even indium-tin oxide coatings with a resistivity as low as 10 ohm/cm2 cannot transport the photocurrent generated with 1 sun irradiance over more than 10 to 15 mm without incurring electrical losses.” (Solar Power Wires Based on Organic Photovoltaic Materials, Science Magazine, 10 Apr. 2009.)

In addition to poor efficiency, solar textile modules made from photovoltaic fibers known in the art are subject to malfunction from shorting of conductors, particularly at connections where charges from multiple fibers are merged. Unless substantially fortified, the delicate nature of the small connections allows them to be damaged from minor impacts or abrasions. Depending on the design, a single short circuit could impair the function of multiple cells, or even adjacent solar modules. Similarly, solar textile modules made from other existing photovoltaic components such as thin films are either too fragile or rigid and are still largely unproven for exploiting the advantages of solar textiles.

These and other technical problems relating to existing photovoltaic components and systems continue to inhibit the rapid commercialization of new applications for solar textiles. Therefore, there is a need in the art for more efficient photovoltaic textile components and materials in general, particularly those that are durable but still flexible enough to exhibit the properties of fabrics.

### SUMMARY OF THE INVENTION

Accordingly, the present invention is directed to novel photovoltaic systems, components, and methods of manufacturing related to solar textiles. In general, the invention improves solar textile performance by taking a systems approach to the overall design. Textiles in accordance with the present invention employ highly conductive bus bars serving as conduits in contact with, such as by interweaving among, elongated photovoltaic components such as PPV tapes or fibers to move charge in and out of textile unit cells. The bus bar conduits minimize charge transport resistance throughout the textile by providing multiple, durable electrical contacts with charged surfaces along the length of the photovoltaic components. The bus bar conduits may also be referred to herein as conductive conduits.

While the description of the present invention is directed to a textile system that converts solar energy to electricity and the effective transport of that electricity, it is not limited strictly to “solar” textiles. Instead, it is directed to any textile that has one or more flexible and elongated charge carrying components, which may be photovoltaic components but that also may be other forms of charge carrying components, including, but not limited to, other forms of flexible conductive elements. The charge carrying components include a first electrode and an oppositely charged second electrode, wherein the first electrode has a charge transport resistance, and one or more flexible and elongated conductive bus bar conduits in contact with the first electrode of at least one of the one or more charge carrying components, the one or more conductive bus bar conduits having a charge transport resistance different from the charge transport resistance of the first electrode.

In one aspect of the invention, systems for converting solar energy into usable electric power are characterized by incorporating at least one solar textile, each comprising two or more photovoltaic components relatively parallel to one another and having conduits of highly conductive bus bar material woven in between. The bus bar conduits are woven perpendicular to the photovoltaic components, but depending upon the requirements of the application, the bus bar conduits may be arranged to cross the photovoltaic components at an angle other than 90°. The contact between the bus bar conduits and the photovoltaic components may also be achieved by other than weaving including, for example and without limitation, by joining them together, such as by a welding or bonding arrangement. In an exemplary embodiment, a solar textile system includes coaxial PPV fibers known in the art. Contact between the photovoltaic fibers and conductive bus bar material minimizes electron transport resistance along the external transparent conductor of the fibers and thereby reduces voltage drop across the textile as a result of the overall system design. In another embodiment, a system includes at least one solar textile comprising elongated photovoltaic components in the form of tapes which make more expansive electrical contact with interwoven bus bar material.

In another aspect of the present invention, the performance of solar textiles is improved by incorporating uniquely constructed conduits of conductive bus bar material. In preferred embodiments, the conductive conduits are manufactured flat as tapes having a substrate formed with an insulating flexible polymer such as polyester or polyimide. When used in association with photovoltaic tapes as described herein, conducting layers are integrated upon the top and bottom planar surfaces of the substrate and the conduit tapes arranged among the photovoltaic components as either warp or weft, depending on the particular embodiment. If used instead with co-axial fibers having a tubular outer electrode, the conductive conduits may be manufactured without multiple conductive layers and in some embodiments as a single conducting layer monolith, without an insulating substrate. Depending on the application, the conductive conduit tapes may be profiled to better conform and make greater electrical contact with photovoltaic components.

In another aspect of the present invention, textiles include novel photovoltaic tapes interlaced among and making electrical contact with highly conductive bus bar conduits. In comparison with coaxial photovoltaic fibers, the photovoltaic tapes generally provide more surface area for electrical contact with conductive conduits used in the solar textiles of the present invention. Together, the photovoltaic tapes and conductive conduits function as unit cells. In preferred embodiments, PPV tapes are segmented such that photovoltaic portions are arranged as a series of in-line rectangles separated by insulating gaps along the length of the PPV tape.

In still other aspects of the present invention, methods are disclosed for manufacturing novel conductive bus bar conduits and photovoltaic components as well as for their combined assembly as textiles.

It will be appreciated by those in the art that it is a feature of certain embodiments of the present invention to provide solar textiles which are basic in construction and easy to weave.

It is another feature of certain embodiments of the present invention to provide solar textiles which separate charge transport, mechanical strength, and photovoltaic functions, enabling optimization of each and making each function independent from the constraints of the other.

It is another feature of certain embodiments of the present invention to provide bus bar conduits and textiles that maximize exposure of photovoltaic components to solar flux.

It is another feature of certain embodiments of the present invention to provide solar textile systems with PPV components and interwoven bus bars.

It is another feature of certain embodiments of the present invention to provide bus bar conduits having geometries for improved electrical contact with photovoltaic components.

It is another feature of certain embodiments of the present invention to provide dual conductor, bi-polar, bi-directional charge carrying bus bar conduits.

It is another feature of certain embodiments of the present invention to provide PPV tapes that are flexible for use in solar textiles.

It is another feature of certain embodiments of the present invention to provide durable solar textiles incorporating PPV tapes.

It is another feature of certain embodiments of the present invention to provide photovoltaic textiles having convenient over and under electrical designs.

It is another feature of certain embodiments of the present invention to provide photovoltaic textiles that may be effectively connected to external circuitry with simple polarized mechanical compression clamps.

It is another feature of certain embodiments of the present invention to provide solar textile systems assembled to minimize electrical losses and maintain the inherent power conversion of photovoltaic components.

It is another feature of certain embodiments of the present invention to provide solar textile systems for optimizing the electrical performance of photovoltaic components including but not limited to photovoltaic co-axial fiber and tape designs.

It is another feature of the certain embodiments of the present invention to provide solar textiles having relatively large electrical contact areas, producing low contact resistance.

It is another feature of the certain embodiments of the present invention to provide efficient solar textiles that are able to stretch, bend, and conform to body contours.

The foregoing and related aspects and embodiments and other advantages and features of the invention will be readily apparent to those skilled in the art after review of the following detailed description of the invention, drawings, and claims.

### BRIEF DESCRIPTION OF THE DRAWINGS

FIG. 1 is a cross section of a conductive bus bar tape having conducting layers on both the top and bottom of an insulating substrate film.

FIG. 2 is an illustration of a photovoltaic textile incorporating multiple bus bar conduits perpendicularly arranged as weft between several photovoltaic tapes that serve as warp. It is to be understood that the bus bar conduits may form the warp and the photovoltaic tapes may form the weft of the textile without deviating from the invention.

FIG. 3 is a cross-section view of two conductive bus bar conduits among a photovoltaic component.

FIG. 4 is a perspective view of a cross section of PPV tape with edge insulators.

FIG. 5 is a perspective view of an area of a solar textile depicting the direction of current.

FIG. 6 is an area of weave in a portion of solar textile that identifies a unit cell.

FIG. 7(a) is a diagrammatic representation of a single unit cell equivalent circuit.

FIG. 7(b) is an array of multiple unit cell equivalent circuits representing the electrical properties of a solar textile.

FIG. 7(c) is a graph showing circuit power output from a fabric product including a textile of the present invention with connecting conductive bas bar conduits and PPV tapes.

FIG. 8 is a cross sectional perspective view of a portion of a solar textile showing the layers of a twin upper electrode PPV tape.

FIG. 9 is a front, perspective view of the solar textile in FIG. 8 wherein PPV tapes serve as weft and conductive bus bar conduits serve as warp of the textile. It is to be understood that the PPV tapes may form the warp and the bus bar conduits may form the weft of the textile without deviating from the invention.

FIG. 10 is a diagonal perspective view of the solar textile of FIG. 8 showing the conductor insulating margins of the bus bar conduits.

FIG. 11(a) is a top perspective view of a processed polymer sheet of conductive bus bar conduit tapes.

FIG. 11(b) is a top view of one of the tapes after separation from the processed polymer sheet of FIG. 11(a).

FIG. 12 is a top view of a portion of solar textile comprising segmented photovoltaic tapes with insulating gaps.

FIG. 13 is a top view of a solar textile comprising segmented photovoltaic and conductive bus bar conduit tapes.

FIG. 14(a) is a top perspective view of a processed polymer sheet of photovoltaic tape.

FIG. 14(b) is a top view of a segmented photovoltaic tape after separation from the processed polymer sheet of FIG. 14(a).

FIG. 15 is an illustration of a coaxial PPV fiber that may be used in the construction of solar textiles.

FIG. 16 is an illustration of a portion of solar textile comprising photovoltaic fibers arranged among monolithic bus bar conduits.

FIG. 17 represents the flow of charges through a portion of solar textile.

FIG. 18 identifies a unit cell within a portion of solar textile.

FIG. 19 is a diagram of an electrical circuit approximately equivalent to a portion of solar textile.

FIG. 20 is an illustration of a portion of solar textile comprising photovoltaic fibers arranged among monolithic bus bar conduits and non-conducting ribbons.

### DETAILED DESCRIPTION OF THE INVENTION

As used herein the term “converting means” refers to a component that is photovoltaic or otherwise produces electricity when exposed to electromagnetic radiation.

The term “deposit” covers all technologies used in coating a surface with a material including but not limited to spraying, dipping, spin coating, vacuum and chemical deposition, printing including, but not limited to, inkjet printing.

The term “electrical appliance” refers to a component that is made operable in function or capacity by current including but not limited to cell phones, global positioning systems, lights, motors, batteries, regulators, inverters, rectifiers, and transformers.

The term “interlaced” means going one over the other as to be woven or intertwined in uniform structure and geometry.

The term “integral” means fixed or made a part of during the manufacturing process.

The term “light” includes a range of electromagnetic radiation known as visible light and portions of infrared and ultraviolet spectrums applicable to generating electricity from photovoltaic components.

When referring to spatial relationships the term “opposing” means oriented away from one another in opposite directions.

The term “oriented uniformly” refers to like components arranged such that their same functional sides are oriented in the same direction.

The term “oppositely charged electrode” refers to an electrode having a relative charge that is opposite the transparent electrode of the same photovoltaic component.

The term “photolithographic method” includes but not limited to the employing of photoresist materials to define and/or transfer a pattern from a photo image onto a deposited layer followed by selective etching. It includes other means of shape control during deposition such as shadow masking and inkjet printing.

The term “photovoltaic” means having a capacity to contribute to the production of electricity across opposite electrodes as a result of being exposed to electromagnetic radiation.

The abbreviation “PPV” is short for polymer photovoltaic and describes a component or system having photovoltaic function which includes a structural polymer and other materials.

The abbreviation “PV” is short for photovoltaic and describes a component or system having photovoltaic function, wherein the photovoltaic may not be a polymeric component.

The term “PV layer” refers to one or more photoactive layers that when combined with another will facilitate the generation and movement of electric charge including an N-layer and a P-layer.

The term “relatively parallel” includes elongated components running alongside each other in the same general direction but not interlacing such as the relationship between neighboring weft or warp fibers in a woven textile.

The term “sliding electrical contact” refers to a low resistance electrical contact interface that is largely maintained as the surfaces making contact are slid, translated, or hinged in relation to one another.

The term “solar textile” includes textiles, cloths, fabrics, and other thread or cord assemblies incorporating photovoltaic components and having varying degrees of flexibility.

The term “tape” refers to a relatively thin and narrow component with two opposing planar surfaces that is particularly longer than it is wide.

The term “transparent” means allowing light to pass through and includes translucent as well as transparent.

The term “transparent electrode” means an electrode which allows light to pass through it to a PV layer or an electrode that is permanently fixed or integrated with a transparent conductive layer immediately covering a PV layer so that the electrode, conductive layer, and the surface of PV layer contacting the conductive layer are in continuous electrical contact and carry approximately the same electrical charge.

The term “wire” includes any conductor whether or not insulated that conducts current to or from an electrical appliance for the intended purpose of the operation of the appliance.

Photovoltaic systems according to the present invention comprise textiles made by weaving conductive bus bar conduits among inherently less conductive photovoltaic components. By incorporating the bus bar conduits in contact with the photovoltaic components, transport resistance and parasitic voltage drops are minimized through the textile as a result of its overall system design.

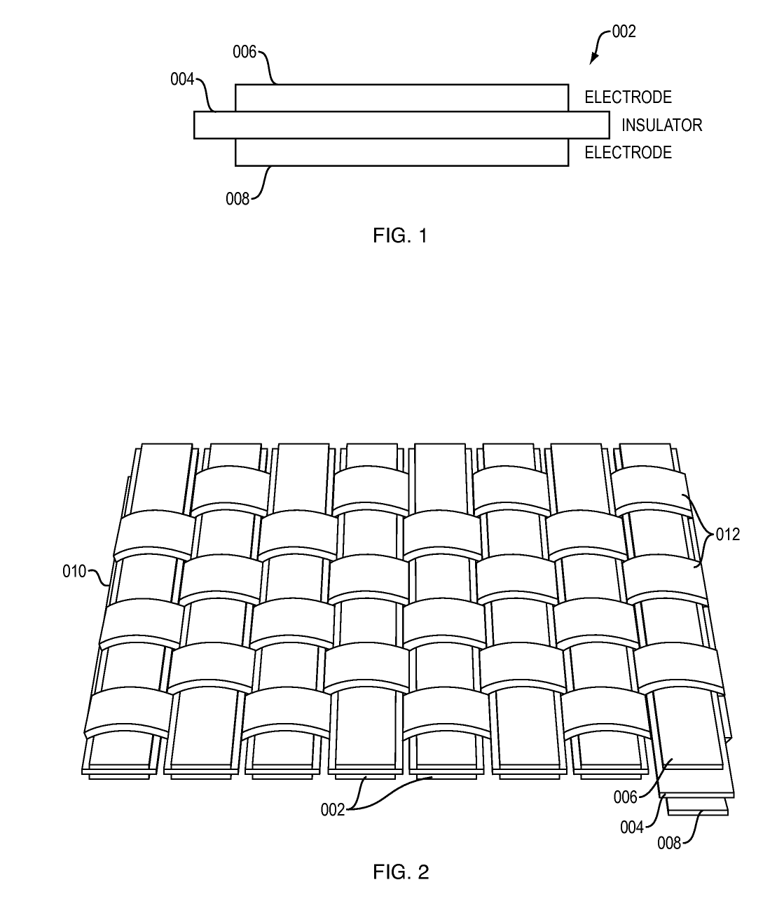

In preferred embodiments, systems of the present invention incorporate conductive bus bar conduits. When used with photovoltaic components having opposing electrode terminals, such as certain PPVs also in the form of tapes but not limited to polymers and not limited to tape configurations, the bus bar conduits include dual conductors with an insulating substrate film separating the conducting layers from each other. Shown in FIG. 1 is a cross section of a conductive bus bar conduit 002 in accordance with the present invention. In this embodiment, an insulating substrate 004 is sandwiched between a top conducting layer 006 and a bottom conducting layer 008. When placed in electrical contact with active photovoltaic components, the conducting layers function as oppositely charged electrodes.

Within the dual conductor bus bar conduit 002 shown in FIG. 1, mechanical and electrical requirements are separately assigned to different layers of the conduit 002. Mechanical strength and flexibility are largely determined by the insulating substrate 004 where the electrical properties of the conduit 002 result from the conducting layers 006 and 008. As a result of this functional division, the insulating substrate 004 of the bus bar tape conduit 002 is optimized for mechanical properties such as tensile strength, bending radius, elongation, and so on, whereas the two conducting layers 006 and 008 are optimized for high electrical conductivity, lowest contact resistance with PPV components, and high resistance to wear.

Shown in FIG. 2 is an area of textile 010 according to a system of the present invention. The textile 010 includes multiple relatively parallel flexible polymer photovoltaic tapes 012 serving as warp in electrical contact with flexible and highly conductive bus bar conduits 002 acting as weft for the textile. The photovoltaic tapes 012 have opposing upper and lower surfaces that develop opposite charges when exposed to light. The photovoltaic tapes are also oriented uniformly among the conduits such that the development of all positive charges and all negative charges is relegated to opposite planar surfaces of the textile. As a result of contact with one of the two opposing surfaces of the photovoltaic tapes 012, the conducting layers 006 and 008 of the bus bar conduit 002 each behave as oppositely charged electrodes in the presence of light. In preferred embodiments, the conducting layers 006 and 008 of the bus bar conduit 002 may be made from highly conductive metals, conducting polymers, or similarly conductive materials.

As shown in FIG. 2, the textile 010 is intended to be shown having approximately 50% polymer photovoltaic tape active area and 50% conductive bus bar conduit area. However, the ratio of the two active areas may be adjusted by changing the dimensions of either or both of those two components of the textile 010. For example, in an alternate embodiment, the textile 010 having bus bar conduit tape 002 with widths reduced by 50% in comparison to the textile 010 shown in FIG. 2 while leaving the widths of the photovoltaic tape 012 the same would have approximately 75% of its surface as active photovoltaic component. Other ratios of photovoltaic active area to conductive bus bar conduit area may be embodied in the present invention as a function of the particular electrical characteristics desired.

Other techniques may also be used to maximize the activity of photovoltaics in textiles according to the present invention. In another embodiment, a solar textile includes PPV components and conductive bus bar conduits having optically transparent insulating substrate films between the conducting layers. The conducting layers are narrower than the transparent insulating substrates to reduce shadowing and expose more PPV material to be photoactive in the textile. In still another embodiment, a solar textile of the present invention includes photovoltaic components among relatively narrow bus bar conduits having conducting layers on top and bottom. Low sheet resistance is achieved by increasing the thickness of the conducting layers of the conduits without impairing optical transmission to the PPV. The conducting layers may be made from metals such as gold, silver, aluminum, copper, or the like and, in the alternative, may be made of conductive coatings. In a preferred embodiment of a conductive coating version of the invention, the conducting coating layer is an aluminum metalized polymer.

It will be appreciated by those skilled in the art that long distance charge transport through the textile of FIG. 2 encounters minimal resistance because charge flow is directed through the highly conductive bus bar conduits rather than through the optically transparent but electrically resistive layers of the PPV tapes. At the same time, the crossing tapes of the textile shown in FIG. 2 form electric contact interface regions which maintain low resistance electrical contact even during movement of the textile, yet the construction still allows the tapes to slide along one another, imparting a fabric-like behavior. As a result, the textile incurs minimal electrical losses and optimizes the electrical power provided by the photovoltaic components while still functioning as a textile.

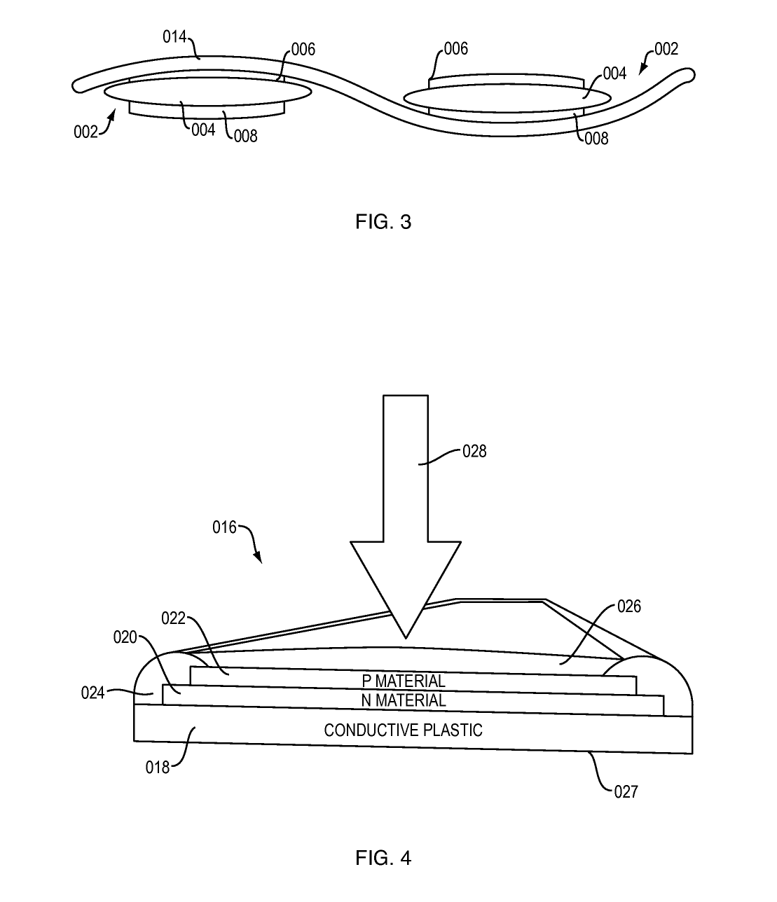

The contact interface performance of solar textiles of the present invention may be further enhanced by modifying the bus bar conduit profile. Shown in FIG. 3 is a pair of dual conductor bus bar conduits 002, each having insulated substrate film 004 between top conductive layer 006 and bottom conducting layer 008. The insulating substrate films 004 of the conduits 002 are shaped such that when the top conducting layers 006 and bottom conducting layers 008 are integrated with the films 004, the resulting cross section profiles of the conduits 002 are curved and conform to a photovoltaic component 014 interlaced over and under the conduit pair, such as in a perpendicular orientation, but not limited thereto.

Photovoltaic components of the present invention may be tapes or fibers or other geometric constructions and may or may not include structural polymers or any polymers at all. For example, one or more of the photovoltaic components may be formed partially or completely of non-polymeric material such as, for example, inorganic materials such as inorganic thin films and combined with the bus bar conduits to form the textile 010. The material must have sufficient flexibility to allow it to move as a fabric without compromise to structural integrity and desired photovoltaic and/or conductive properties. Materials that are formed thin enough to be flexible or that have inherent flexibility may be suitable. Inorganic materials suitable for the purpose include, but are not limited to, amorphous Silicon, Copper-Indium-Gallium-Selenide, Cadmium-Telluride, and the like can equally well be used in the implementation of the photovoltaic textile structures of the invention. An embodiment of a photovoltaic component of the present invention is a photovoltaic tape 016 shown in FIG. 4. The photovoltaic tape 016 may be a polymeric photovoltaic tape but is not limited to the inclusion of polymeric material in its fabrication. The PPV tape 016 includes a flexible and conductive backbone 018 defining the overall width of the tape. The backbone 018 can be a metal, a conductive polymer or a stack of layers of metal and conductive polymers chosen to achieve simultaneously, good electrical conductivity, mechanical strength and flexibility. Adjacent to an upper surface of the backbone 018 is a slightly narrower N layer 020. Above the N layer is an even narrower P layer 022. The backbone 018 and the N and P layers 020 and 022 are sequentially in physical and electrical contact with one another, forming the P-N junction structure needed for photovoltaic conversion. In general, other structures may provide the photovoltaic conversion provided by the tape 016 without deviating from the invention. For example, the photovoltaic component may include other layers in between the P-N junction structure. Both edges of the N and P layers 020 and 022 as well as the upper surface of the backbone 018 that is not in contact with the N layer 020 are covered by a flexible edge insulator 024 along each side of the tape 016. Between the two edge insulators 024 and above the P layer 022 is an uppermost layer of optically transparent, electrically conductive material serving as upper electrode 026. A lower electrode 027, carrying a relatively opposite charge is established at the lower surface of the backbone 018 and may be the backbone 018 itself, or a lower portion thereof. Optically transparent upper electrode 026 may be formed of ITO or PEDOT or any suitable optically transparent material having some conductivity. Layers 020 and 022 are of differing widths, as shown.

Both electrodes 026 and 027 of the tape 016 shown in FIG. 4 run along the entire length of the tape 016, and form all or a part of opposite external surfaces thereof. The material of the upper electrode 026 is selected to allow light 028 to pass therethrough. The light 028 passes through the upper electrode 026 and reaches the P layer 022. Below the edge insulator 024, the differing widths of layers 020 and 022 form layer insulating margins to ensure electrical separation between the voltage creating layers. When the tape 016 is positioned alongside neighboring tapes, it is prevented from making electrical contact with its neighbors by the flexible edge insulator 024. The edge insulator 024 also protects the edges of layers 020 and 022 from becoming damaged from friction, impacts, or the like.

The photoactive and accompanying layers of materials may be deposited on the conductive polymer backbone and assembled together using present lithographic methods known in the art. When finished, the tape assembly can then be unrolled and fed as needed into looms of various types to create numerous textile weaves.

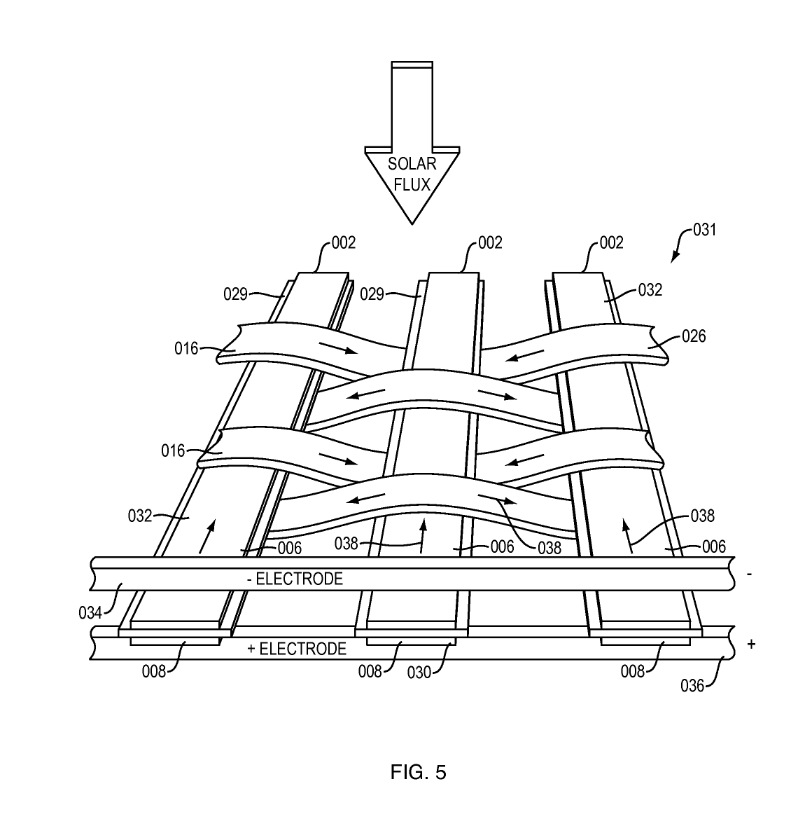

Another embodiment of a textile 031 according to the present invention is shown in FIG. 5. As with the tape 016 of FIG. 4, photovoltaic components of the textile of FIG. 5 may or may not be formed of polymeric material and include electrodes 026 and 027 on both upper and lower surfaces. The tapes 016 of FIG. 5 are oriented roughly uniformly in parallel with each other as warp of the textile 031 and interlaced roughly perpendicularly with three conductive bus bar conduits 002 that serve as weft of the textile 031. Each conductive bus bar conduit 002 is also a tape as previously described, with insulating regions 029 between top and bottom conductive layers 002. As shown, the top conducting layer 006 of center bus bar conduit 030 is in electrical contact with the negative electrodes 027 of alternate ones of the tapes 016 and the tapes 016 not in contact with the top conducting layer 006 of the center bus bar conduit 030 are in electrical contact through their negative electrodes 027 with the top conducting layers 006 of each of end bus bar conduits 032. As the PPV tapes 016 are activated by solar flux, negative charges are developed on the lower electrode surfaces 027 of all PPV tapes 016 in the textile 031. The negative charges are transferred to the top conducting layers 006 of all three bus bar conduits 030 and 032 and to a common negative electrode terminal 034 also in electrical contact with the top conducting layers 006 of the bus bar conduits 002. Similarly, positive charges from the upper electrodes 026 of all the tapes 016 are conducted to a common positive electrode terminal 036 by way of electrical contact with the bottom conducting layers 008 of all three bus bar conduits 002. As a result of the uniform bipolar, bidirectional nature of the textile 031, a simple bipolar, mechanical compression clamp may be used to make electrical connections with the electrode terminals 034 and 036 to complete an electrical circuit. When the connections are made, current 038 is established in an electrical circuit from the positive electrode terminal 036 and returns through the negative electrode terminal 034 to the lower surfaces 027 of the tapes 016.

A pattern of electrical current 038 through the textile 031, when the textile 031 is made part of completed circuit, is represented as arrows on the bus bar conduits 002 and tapes 016 as shown in FIG. 5. The current 038 encounters minimal resistance from the textile 031 because of the relatively large and abundant tape to tape electrical contact interfaces between areas of the tapes 016 and areas of the conductive bus bar conduits 002. In addition, electrical resistance resulting from charge transport is reduced because of the multiple contact points along the length of each photovoltaic component. In the embodiment of the textile 031 shown in FIG. 5, the maximum charge transport distance on each tape surface is approximately half of the bus bar conduit pitch. However, charge transport distance may be varied in other embodiments according to the particular photovoltaic components and bus bar materials chosen, as well as the structure of the weave.

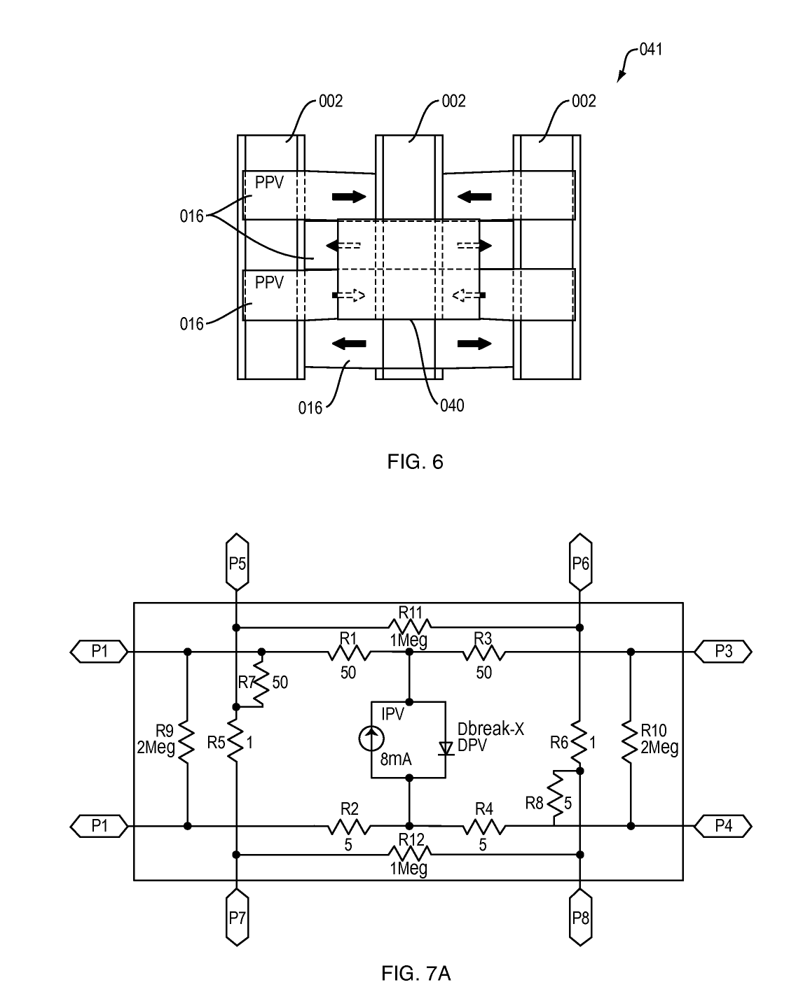

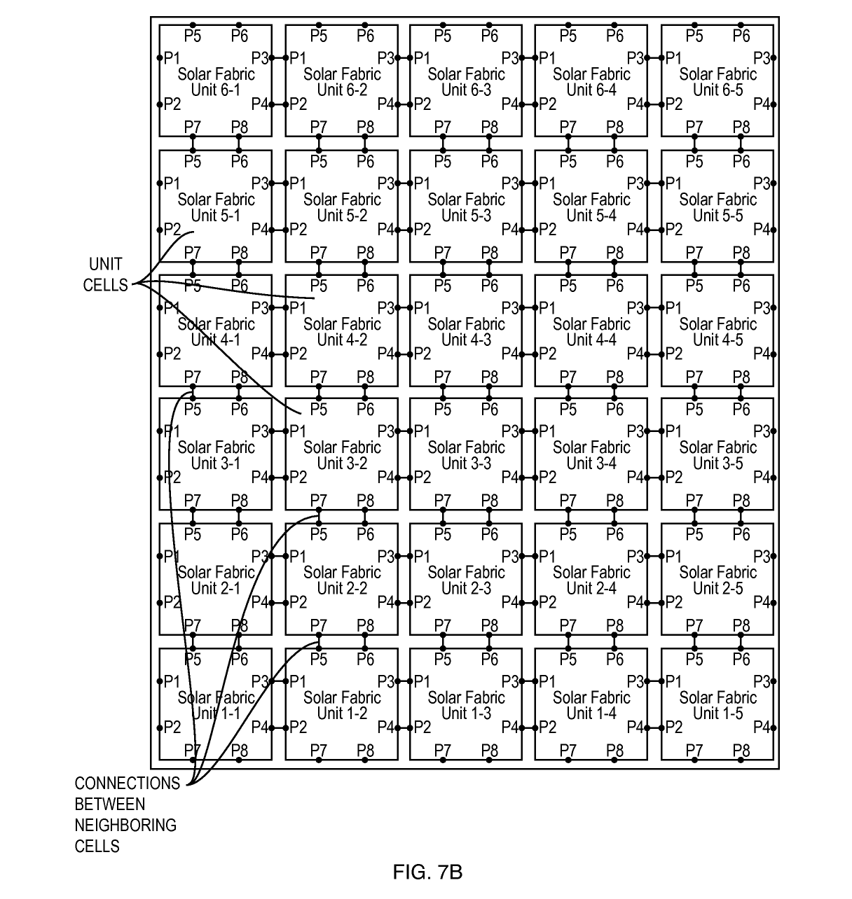

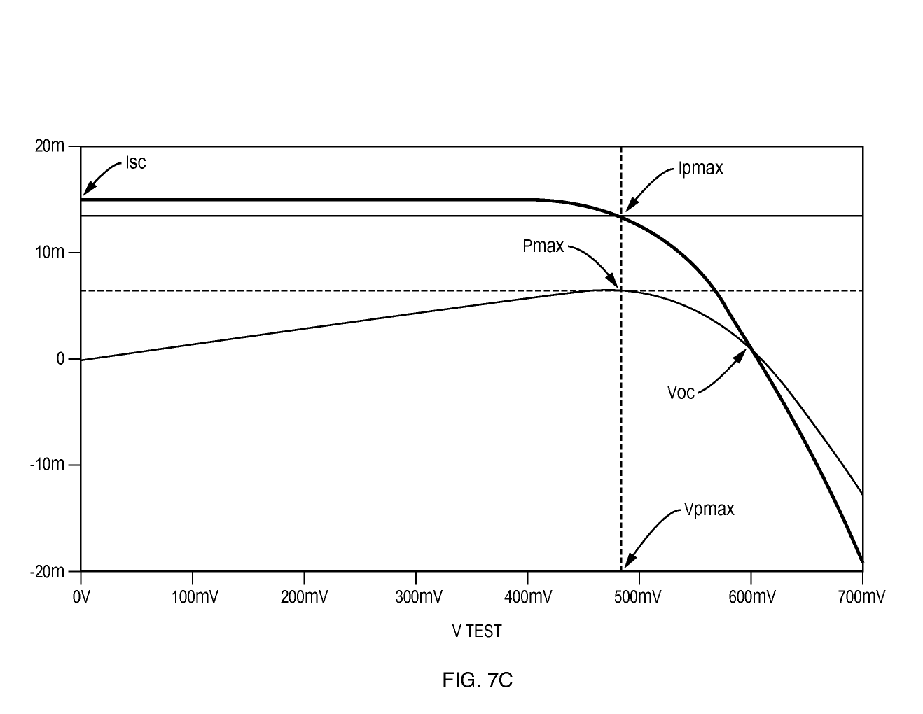

In another embodiment of a textile 041 of the present invention, the textile 041 is a woven product having tapes 016 with opposing electrodes on upper and lower surfaces as previously described. As shown in FIG. 6, the tapes 016 are oriented roughly uniformly and arranged roughly perpendicularly among conductive bus bar conduits 002 that serve as weft of the textile 041. The conductive bus bar conduits 002 are also tapes with top and bottom conducting layers as previously described. Current through the textile 041 is represented by arrows. As identified by a representation of a conductive unit cell 040 shown as a semi-transparent rectangle in FIG. 6, a woven product formed of the textile 041 includes a plurality of individual ones of such unit cells 040. Each unit cell 040 is a two-dimensional array and each unit cell 040 abuts at least one other unit cell 040. Each unit cell 040 is approximately characterized by the same potential for electrical activity and electrical contact with bus bar conduits per area of the textile 041, which is approximately described in a diagram of an equivalent electrical circuit shown in FIG. 7(a) using the label definition key of Table 1. It is to be understood that the equivalent circuit of FIG. 7(a) is an approximate model of the circuit that would be produced rather than a precise representation of it. Of course, other circuit configurations may be established through adjustments of the locations and characteristics of the photovoltaic tapes and the conductive conduits.

TABLE 1
Unit Cell Equivalent Circuit Definitions

| Label | Component | Function |
|---|---|---|
| IPV | Current source | Component of photovoltaic model (PV unit) |
| DPV | Diode | Component of photovoltaic model (PV unit) |
| R1 | Resistor | ½ of effective sheet resistance of optically transparent top layer (positive) |
| R3 | Resistor | ½ of effective sheet resistance of optically transparent top layer (positive) |
| R2 | Resistor | ½ of effective sheet resistance of bottom conducting layer (negative) |
| R4 | Resistor | ½ of effective sheet resistance of bottom conducting layer (negative) |
| R9 | Resistor | Edge losses on one side of tape within cell |
| R10 | Resistor | Edge losses on one side of tape within cell |
| R7 | Resistor | Contact resistance between cell and positive (+) bus bar electrode |
| R8 | Resistor | Contact resistance between cell and negative (−) bus bar electrode |
| R5 | Resistor | Axial resistance of positive (+) bus bar electrode |
| R6 | Resistor | Axial resistance of negative (−) bus bar electrode |
| R11 | Resistor | Edge losses or leakage between bus bar polarities |
| R12 | Resistor | Edge losses or leakage between bus bar polarities |
| P1, P3 | Connection | Interconnection of optically transparent top conductor to neighbor cells |
| P2, P4 | Connection | Interconnection of bottom unit cell conductor to neighbor cells |
| P5, P7 | Connection | Interconnection of positive (+) bus bar unit cell to neighbor cell bus bar |
| P6, P8 | Connection | Interconnection of negative (−) bus bar unit cell to neighbor cell bus bar |

Multiple unit cell equivalent circuits are combined to model the electrical performance of a textile as shown in FIG. 7(b). The array shows a two-dimensional rectangular array with each square box representing a standard equivalent electrical circuit as described by FIG. 7(a). Electrical performance of the textile is represented by the total sum of equivalent circuits and electrical connections between neighboring cells. Each equivalent circuit is a separate “object” and specific values of individual unit cells may be modified from the standard to simulate specific characteristics, properties, or events such as, but not limited to, local mechanical damage, local shorting, and long-term wear or degradation. Such modeling provides data for the design and optimization of final textile products.

As an example, current versus voltage output for a specific textile model possessing exemplary electric properties is predicted as shown in FIG. 7(c). The operating point at which maximum electrical power is produced is identified as Pₘₐₓ.

Embodiments of the tape for textiles described thus far are only examples of the many that may be constructed according to the present invention. Textiles having other weaves attaining functional objectives of the present invention are possible using the same photovoltaic components and conductive bus bar conduits. Moreover, many more tape to tape products are made possible by varying the geometric structures of photovoltaic components or bus bar conduits as well as their orientations with respect to one another.

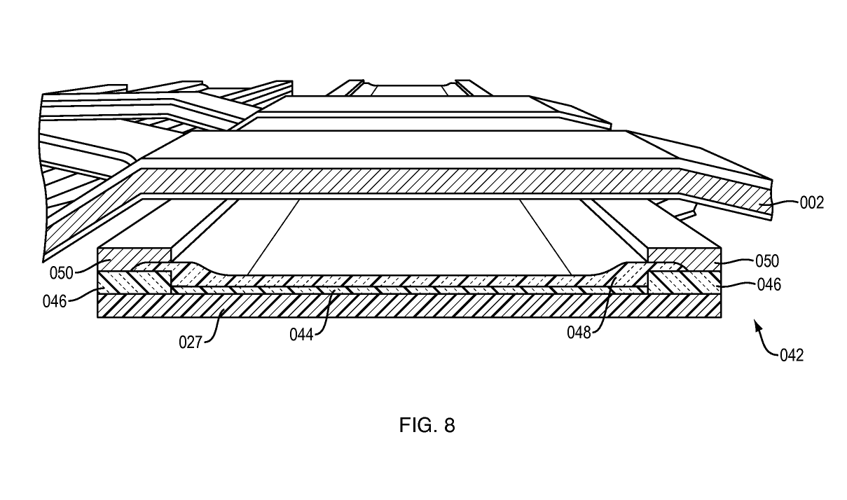

In another embodiment of photovoltaic components of the present invention, a flexible tape 042, which may or may not be a PPV tape, is provided having twin upper electrodes and upper and lower surfaces. The tape 042 is used with dual conductor bus bar conduits 002 as shown in FIG. 8. A lower surface of the tape 042 is a flexible conductive substrate that establishes the overall width of the tape 042 and serving as the lower electrode 027. Centered upon a top surface of the conductive substrate 027 is a narrower photovoltaic layer 044 for creating voltage, which is flanked on both sides by insulating strips 046 also in contact with the top surface of the conductive substrate 027 along both sides of the tape 042. Covering the photovoltaic layer 044 but only partially laying over the top surface of each insulating strip 046 is a recessed, optically transparent conductive layer 048. Above each insulating strip 046 and in electrical contact with the optically transparent conductive layer 048 is a conducting strip 050 along each side of the tape 042. The conducting strips 050 that are twin upper electrodes 050 of the photovoltaic layer 044 define the uppermost surface of the tape 042 and reduce the potential wear from bus bar conduits that would otherwise have occurred on the transparent conductive layer. The lower electrode 027 and the twin upper electrodes 050 of the tape 042 run along the length of the tape 042 and provide low resistance electrical contact areas suitable for conductive bus bar conduits of the present invention.

The tape 042 of FIG. 8 may be fabricated by methods suitable for batch processing. In a preferred embodiment, multiple tape precursors are fabricated on a common flexible and conductive substrate sheet. The photovoltaic, insulating strip, transparent, and conductive layers of adjoining tape precursors are deposited on the flexible conductive substrate sheet using etching and photolithography techniques known in the art. To simplify fabrication, tape layers are deposited on the substrate sheet side by side and adjoining one another in such a way that when all the layers are deposited the tapes are separated lengthwise by slitting with a laser through a center line on each conducting strip 050. Preferably, the method incorporates a polyester plastic sheet that has been made conductive using vacuum metallization, producing highly conductive flexible tapes with very smooth surfaces and having a roughness on the order of 100 nm. It is to be noted that the sheet may have a conductive layer, such as a metal layer, on its surfaces, the polymeric material may be conductive throughout, or a combination of the two.

As with the tape 016 shown in FIG. 4, twin upper electrode photovoltaic tapes may also be fabricated with flexible edge insulators to prevent electrical contact between neighboring photovoltaic tapes. Unless such edge insulators are present or additional insulating material is woven between neighboring components, contact between neighboring photovoltaic tapes is likely, particularly if the photovoltaic tapes are arranged as warp in the textile. Absent these precautions, significant contact between neighboring photovoltaic components may produce short circuits that impair the efficiency of the textile.

In other embodiments of the present invention, photovoltaic components may instead be arranged as the weft of a textile. In these configurations, conductive bus bar conduits reduce the tendency for neighboring photovoltaic tapes to make electrical contact between oppositely charged layers.

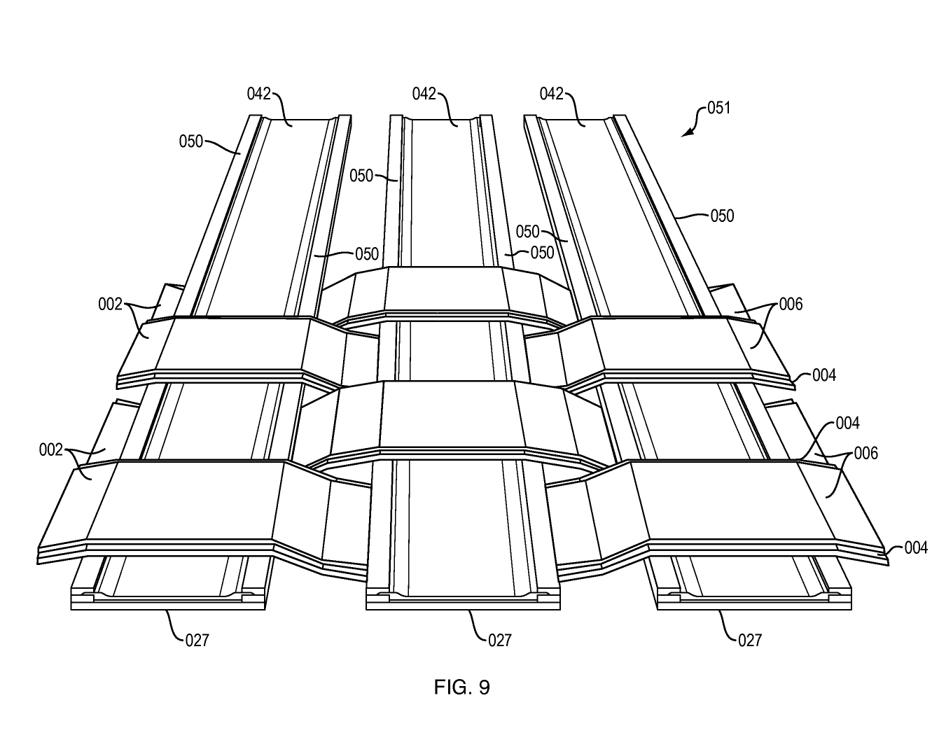

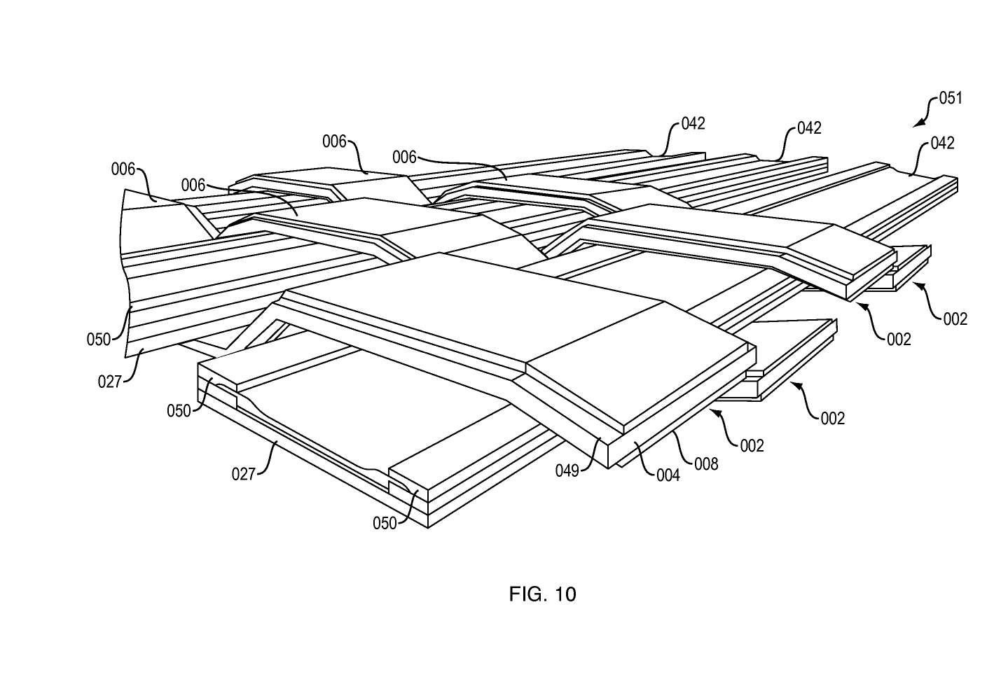

Shown from different perspectives in FIGS. 9 and 10, a textile product 051 includes the tapes 042 oriented roughly uniformly in parallel with one another and arranged roughly perpendicularly among conductive bus bar conduits 002. The bus bar conduits 002 are dual conductor tapes each with the insulating substrate film 004 separating the top conducting layer 006 and the bottom conducting layer 008 as previously described. The insulating substrate film 004 is wider than the conducting layers 006 and 008 and provides conductor insulating margins 049 on both sides of the bus bar conduits 002. Low resistance electrical contact is maintained between the conducting strips 050, which are the upper electrodes 026 of the tapes 042, and the bottom conducting layers 008 of the bus bar conduits 002. Low resistance, electrical contact is similarly maintained between each lower electrode 027 of the tapes 042 and the top conducting layers 006 of the bus bar conduits 002. The tapes 042 of the textile 051 of FIGS. 9 and 10 produce a voltage gradient when exposed to light that is distributed by the bus bar conduits 002 throughout opposing planar surfaces of the textile 051. Thus, the textile 051 may provide current to an electrical circuit after the current is gathered by common electrode terminals or may distribute current to circuits in an isolated fashion from multiple places on planar surfaces of the textile 051. In alternate embodiments, textiles may instead be constructed with photovoltaic tapes arranged among conductive bus bar conduits at angles which deviate from 90 degrees, without increasing resistance to current flow through the textile.

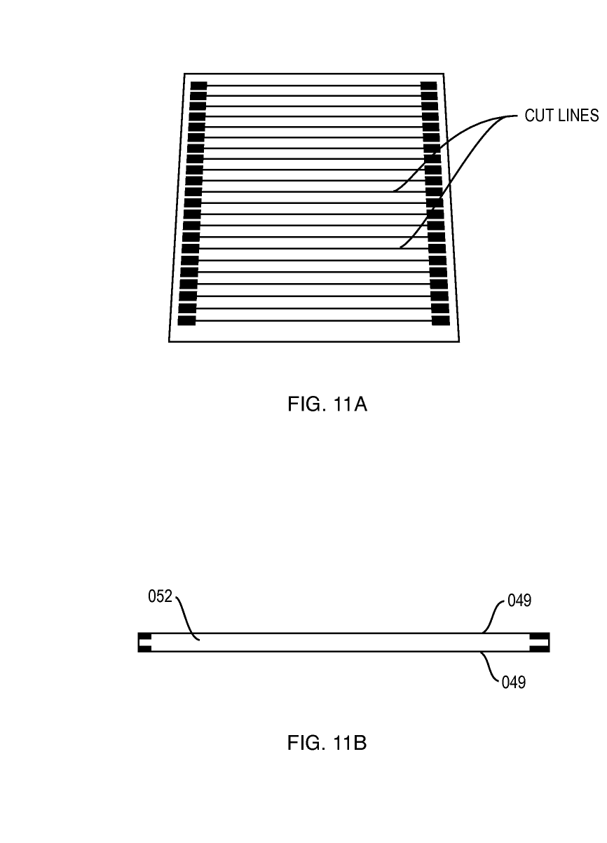

The bus bar conduits 002 of the textile 051 shown in FIGS. 9 and 10 may be fabricated from sheets of polyester film using contemporary photolithography methods. In a particular embodiment of the present invention represented by FIGS. 11(a) and 11(b), dual conductor bus bar conduits (also referred to herein as tapes in certain dimensional configurations) are fabricated by vacuum depositing metal in multiple rows on each side of a polyester sheet. The deposited metal is spaced such that longitudinal portions of non-metalized sheet remain between the rows, as shown in FIG. 11(a), which represents a polyester sheet with multiple metal rows and non-metalized portions running from left to right. After the conduits are individually separated from the sheet by cutting between the rows, the remaining portions of non-metalized sheet on the sides of the conduits provide for substantial non-metal, conductor insulating margins 049, as shown in FIG. 11(b), which represents a single bus bar tape, laser slit and separated from the polyester sheet. When a finished bus bar conduit tape is made part of a textile, the deposited metal rows 052 serve as top and bottom conducting layers and the conductor insulating margins 049 on each side of the rows prevent inter-layer short circuiting within the conduit tape as well as short circuiting between neighboring conductive bus bar conduits. The polyester sheet between the metal layers deposited on opposing sides or faces of the sheet is the insulating substrate film 004 described herein. It is to be understood that other materials may be used to fabricate the insulating substrate film 004 provided that such materials have electrical and physical properties that allow the bus bar conduit 002 to perform as described herein.

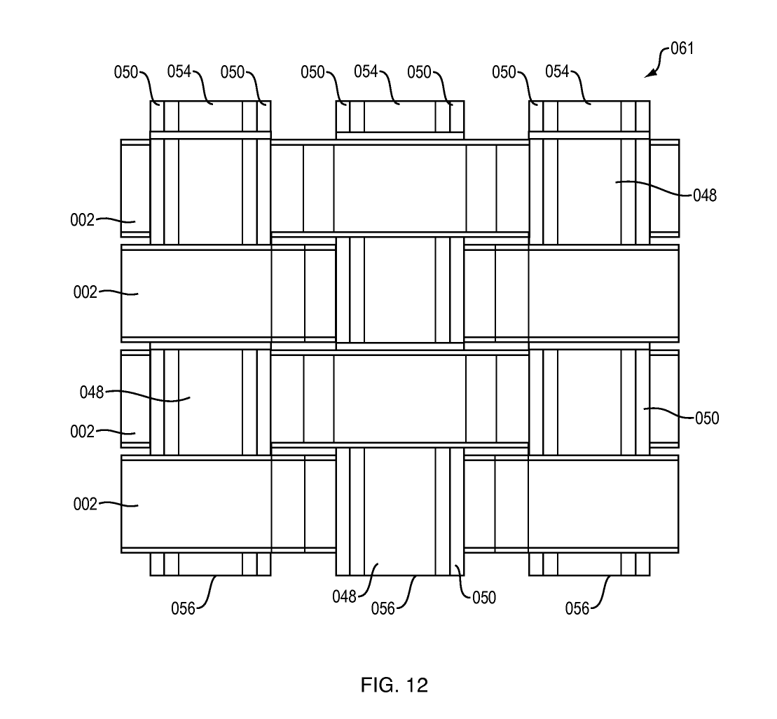

In another aspect of the present invention solar textiles systems having multiple solar unit cells are assembled comprising segmented photovoltaic tapes. The textiles are electrically connected to circuits for storing or transferring electrical power converted from sunlight. Illustrating a preferred embodiment of such systems, a portion of a solar textile 061 comprising segmented PV tapes 054 is shown in FIG. 12. Each PV tape 054 includes multiple layers including a photoactive layer sandwiched within additional layers of material and is configured as weft of the textile 061, with dual conductor bus bar conduits 002 serving as warp. In the uppermost portions, the PV tapes 054 include a recessed, optically transparent, electrically conductive layer 048 and conducting strips 050 corresponding to the twin electrodes 050 described with reference to FIGS. 9 and 10 along each side of each tape 054. In the lowermost portion a conductive polymer substrate serves as the lower electrode.

The conducting strips 050 define the uppermost surface of the PV tapes 054 and are in low resistance electrical contact at multiple points along their lengths with the conductive bus bar conduits 002. However, rather than running continuously along the full length of the PV tapes 054, the conducting strips 050 are segmented with insulating gaps 056 running roughly perpendicularly and spaced periodically along the length of the PV tapes 054 such that two successive insulating gaps 056 define each segment, and each segment length is approximately the same as the width of two conductive bus bar conduits 002. The insulating gaps 056 on each tape 054 electrically isolate rows of segments in which multiple solar unit cells are connected as groups within the textile 061 to provide protection from shorting of the entire length of PV tape 054 should the textile 061 be subjected to damaging forces. In preferred embodiments, the insulating gaps 056 include voids which exist through all but the conductive substrate. When connected to complete an electrical circuit, charge from the textile 061 may be gathered through a common electrode terminal or connected by rows of unit cells to provide power to single or multiple circuits on a row by row basis.

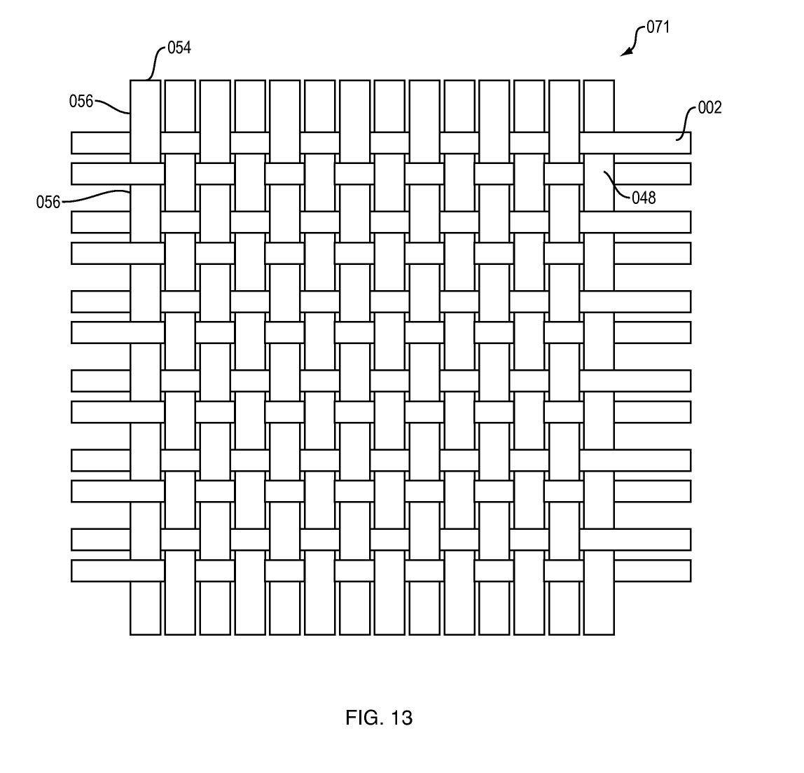

In another aspect of the present invention, a segmented PV tape 054 may be used with dual conductor bus bar conduits 002 as shown in FIG. 12 or, in other embodiments, may be used in other arrangements with different bus bar conduit constructions. Similarly, segmented PV tapes of the present invention can be fabricated having other geometries that may be used as either warp or weft of solar textiles. In a preferred embodiment, relatively parallel segmented PV tapes serve as warp of a solar textile 071 among relatively parallel dual conductor bus bar conduits 002 as represented by FIG. 13. Each PV tape 054 includes multiple layers, making the tape 054 photoactive. The uppermost layer of each PV tape 054 includes the optically transparent conductive layer 048 described with reference to FIG. 8 that is segmented by the insulating gaps 056 of the tape 054 of FIG. 12. The optically transparent conductive layers 048 of the PV tapes 054 are not recessed, so as to make low resistance electrical contact with the bus bar conduits 002 directly rather than with protruding, conductive strips. Moreover, the insulating gaps 056 of the PV tapes 054 are extended to encircle each segment of the tapes 054 so as to electrically isolate the segments from one another as well as from segments of adjoining PV tapes 054. In alternate embodiments, PV tapes may be fabricated with extended insulating gaps encircling segments on both the upper and lower conducting surfaces of the PV tapes.

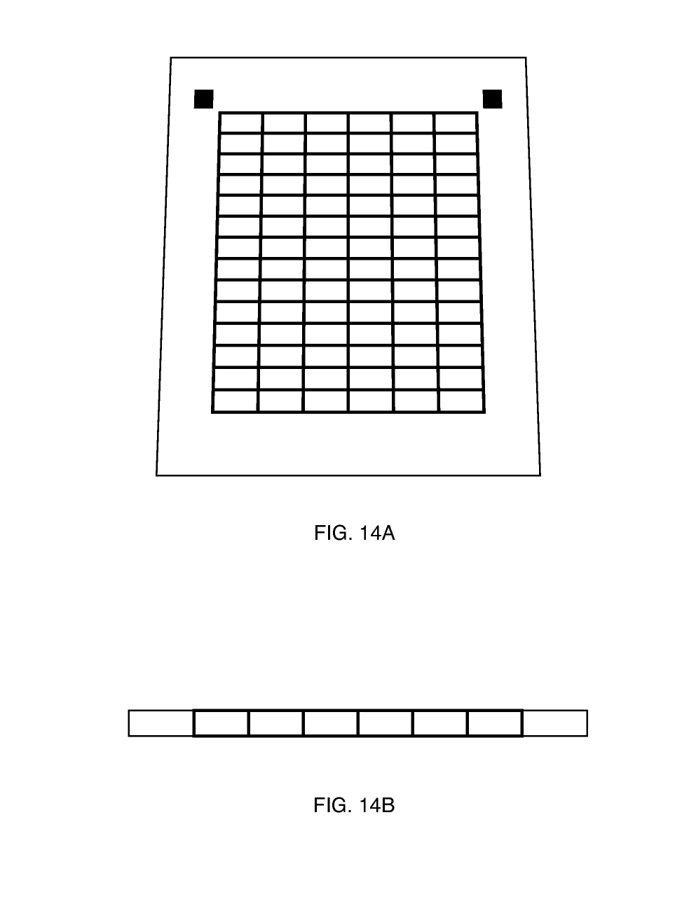

Segmented PV tapes may be fabricated by methods suitable for high volume processing. Multiple tape precursors may be fabricated side by side on a single sheet and later split into individual PV components. Shown in FIG. 14(a) is a flexible polyester sheet after being processed through etching steps known to those skilled in the art of semiconductor device fabrication, for example, wherein layers are built up and portions removed as laid out through photolithographic processes. Individual tapes may be separated by cutting between successive rows, as shown in FIG. 14(b), which represents a single PV tape, laser slit and separated from the polyester sheet. It is to be understood that materials other than polyester may be used to fabricate the insulative portion of the tape provided that such materials have electrical and physical properties that allow the PV tapes to perform as described herein.

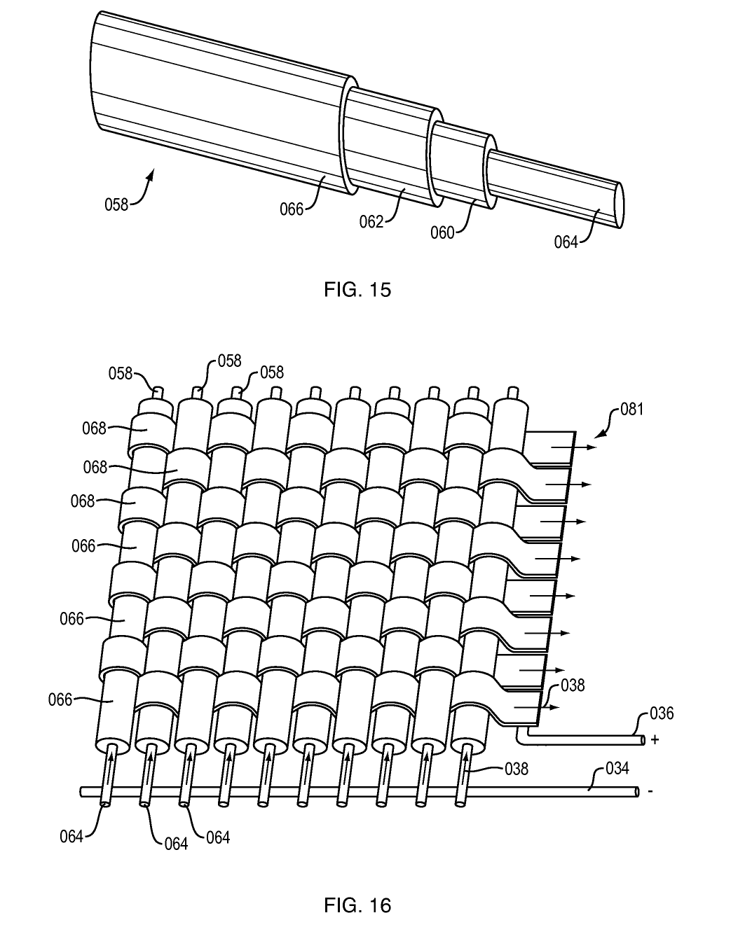

In another aspect of the present invention, photovoltaic textile systems include cylindrical fibers as photovoltaic components. Shown in FIG. 15, a coaxial photovoltaic fiber 058, which may or may not be polymeric, has an inner layer 060 and an outer layer 062 of material which together function as voltage creating layers of a photoactive core. Along a central axis of the fiber 058 is an inner conductor 064 of metal or conductive polymer in electrical communication with the photoactive core so as to serve as a negative electrode. Covering the photoactive core of the fiber 058 is an optically transparent, conductive coating 066 functioning as an external positive electrode when the fiber 058 is exposed to light. As with PV tape based designs, photovoltaic fibers are relatively resistant to charge flow and charge transport through a PV fiber textile may be improved by incorporating conductive bus bar conduits. However, in the case of textiles having co-axial PV components as shown in FIG. 15, the bus bar conduits may be simple monolithic tapes made from conductive material.

Shown in FIG. 16, a portion of a solar textile 081 includes coaxial PV fibers 058 arranged in an interwoven manner among highly conductive monolithic bus bar conduits 068. The monolithic bus bar conduits 068 are made from highly conductive material and are in electrical contact with the optically transparent, conductive coatings 066 of the fibers 058. Each monolithic bus bar conduit 068 is also electrically connected to a positive electrode terminal 036 through which positive charges from the fibers 058 are gathered. Similarly, the inner conductor 064 of each fiber 058 is commonly connected to a negative electrode terminal 034. When the textile 081 is exposed to light and interconnected with other parts of a functioning electrical circuit, the monolithic bus bar conduits 068 compensate for electrical resistance in the optically transparent conductive coating 066 of the fibers 058 and efficiently move current 038 through the solar textile 081 with minimal voltage drop.

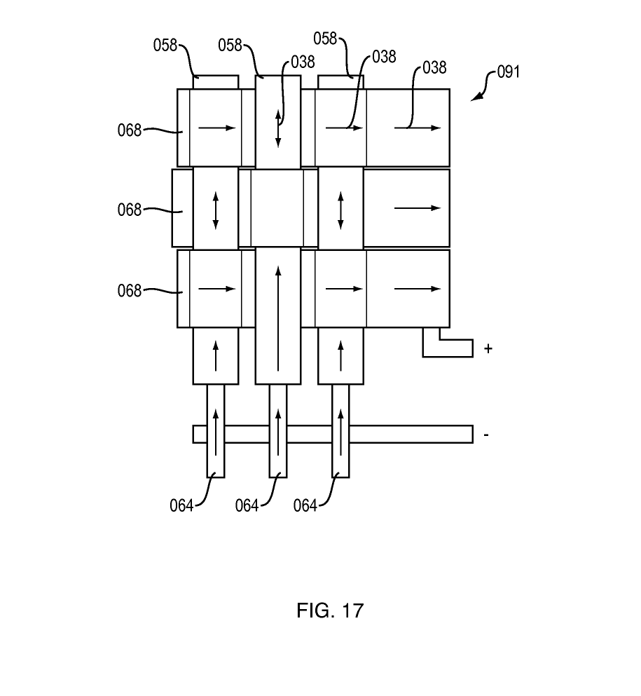

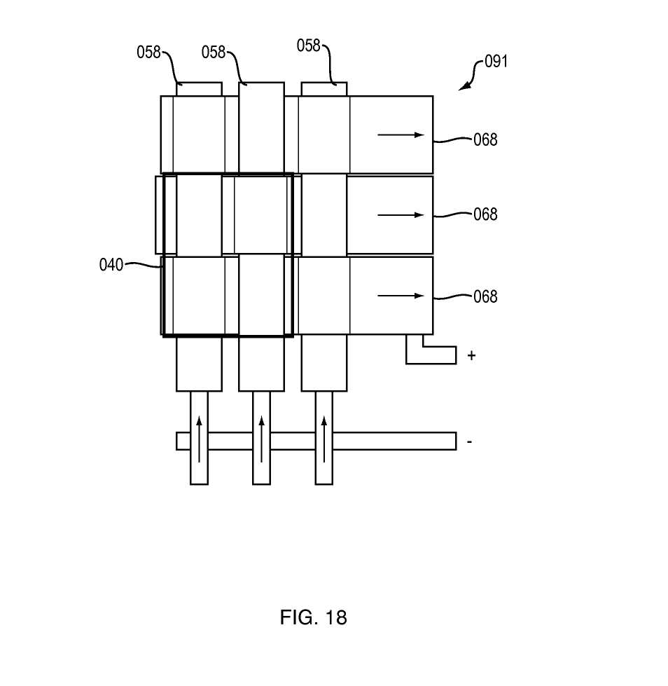

Referring now to FIGS. 17 and 18, current 038 is shown through portions of a particular embodiment of a coaxial photovoltaic fiber textile 091. Within the textile, the fibers 058 are arranged in a direction, such as the weft direction but not limited thereto, among the monolithic bus conduits 068, which transport charge across the textile 091 in only one general direction. When the textile 091 is made part of a functioning circuit, charge flows into the textile 091 via the inner conductor 064 of each fiber 091 and exits in a perpendicular direction via the monolithic bus bar conduits 068.

As with solar textiles comprising photovoltaic tape components, the textile 091 shown in FIGS. 17 and 18 includes multiple unit cells 040. As represented by the semi-transparent rectangle in FIG. 18, the unit cells 040 are two-dimensionally arrayed and abutting one another throughout the textile 091. Within the unit cells 040, electrical current created by the photovoltaic fibers 058 moves toward the conductive bus bar conduits 068. More specifically, each unit cell 040 is characterized by distinct electrical activity relating to a portion of the photovoltaic fiber 058 influenced by proximity and contact with the conductive bus bar conduits 068.

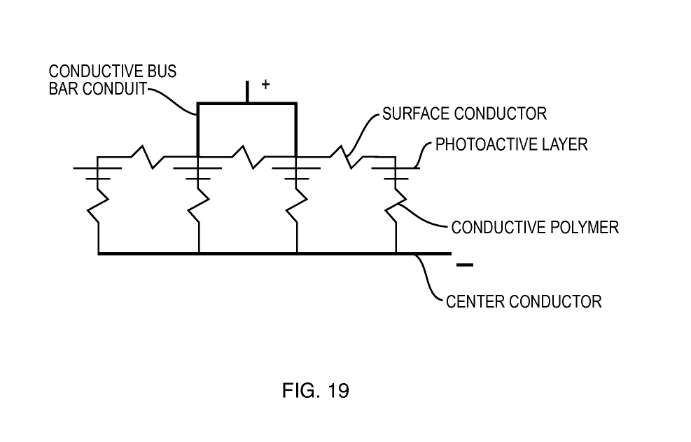

Referring generally now to fiber based textiles of the present invention, the behavior of unit cells may be approximately described by circuit diagrams unique to a particular weave or design. As an example, FIG. 19 shows a simplified equivalent circuit diagram for an embodiment of a coaxial fiber based textile, according to the present invention. The diagram is representative of a solar textile having unit cells comprising PV fibers in contact with conductive bus bar conduits. Each PV fiber includes photoactive layers constructed between an inner or center conductor and an external surface conductor in electrical contact with a conductive bus bar conduit. Completion of the electrical circuit entails common termination of all conductive bus bar conduits forming an anode, and common termination of the center or inner conductors of the PV fibers forming a cathode. Termination of the PV fiber center conductor requires removal or “stripping” of the PV active sections, exposing only the inner conductor. Once exposed, the inner conductors may be terminated as a group. The anode and cathode may then be interconnected with electrical appliances to form a completed circuit. While circuit diagrams for different photovoltaic fiber textile products may differ, it is preferable that highly conductive bus bar conduits be placed in electrical contact with photovoltaic fibers to reduce voltage drop which would normally be associated with long distance charge transport across the textile.

In embodiments of solar textiles comprising coaxial PV fibers, bus bar conduits are formed of flexible but highly conductive materials including but not limited to gold, silver, aluminum, copper, or the like. In such embodiments, the conduits may be simple thin metal monolithic strips or tinsel. When woven, the conduits conform to the outer surface perimeter of the PV fibers, essentially wrapping around the external transparent electrode of the fibers and creating low resistance electrical contact.

In other embodiments, bus bar conduits may provide similar properties but instead may be fabricated as conducting coating layers on top of various flexible substrates. In a particular embodiment, a relatively narrow conducting layer runs lengthwise along the top of a transparent, insulating tape to potentially expose a greater area of fibers to light. Bus bar conduits with conducting layers or strips of significantly narrow widths may require greater cross sectional area in the conducting layer to reduce resistance to charge flow. In some circumstances, such bus bar conduits may be fabricated so that the conducting layers or strips are thicker in height so as to provide adequate cross section and electrical conductivity.

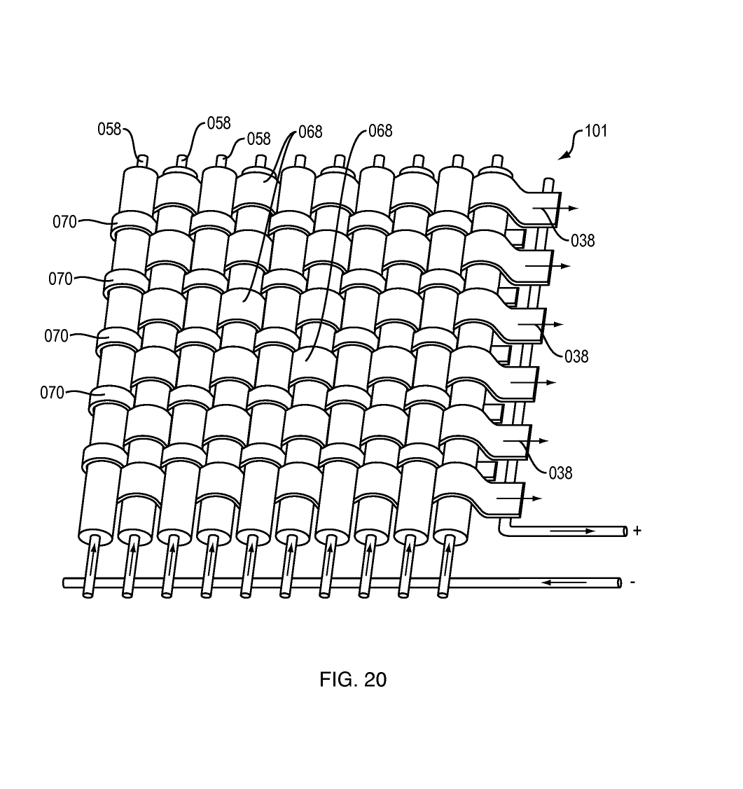

Another embodiment of a solar textile 101 incorporating photovoltaic fibers is shown in FIG. 20. The textile 101 includes PV fibers 058 arranged roughly perpendicularly among a series of conductive bus bar conduits 068 and multiple non-conducting ribbons 070. The conductive bus bar conduits 068 are monolithic tapes and each non-conducting ribbon 070 is woven across the fibers 058 relatively parallel to the bus bar tapes 068 and in an alternating fashion, such that all the ribbons 070 and all the tapes 068 cross a particular fiber 058 on opposite planar surfaces of the textile 101. By alternating in this way, the ribbons 070 and bus bar conduit tapes 068 serve as warp for the textile 101 although each conductive bus bar conduit 068 remains insulated from its neighbors.

Still referring to the textile 101 of FIG. 20, the non-conducting ribbons 070 provide added strength as well as insulation between groups of unit cells of the textile 101. Inner and external electrodes of the PV fibers 058 are commonly terminated and current 038 flows through the textile 101 as represented by the arrows. However in alternate embodiments, fibers or bus bar conduits or both may be terminated individually to electrically isolate multiple groups of unit cells or provide protection from shorts that might otherwise hinder a large area of a given solar textile. In preferred embodiments, non-conducting ribbons are transparent to avoid blocking solar radiation to photovoltaic fibers 058. In other embodiments, ribbons may be opaque and/or take the form of other geometries such as: cylindrical, rectangular, triangular, or prismatic cords and the like.

Referring once again generally to textiles of the present invention, many other products are possible making use of conductive bus bar conduit networks. Altering the selection of conductors, PV fibers or tapes, non-conducting ribbons, and the corresponding geometries of each provides a means to optimize design and performance features in various textile products. Further, the charge carrying component may be something other than a PV component such that the textile for effective conduct of electrical charges may be something other than a solar textile.

As described herein, persons skilled in the art will understand that novel systems, components, and methods for fabricating improved solar textiles are herein disclosed which resolve significant shortcomings in the prior art. The embodiments provided are intended only as exemplary illustrations and not for the purpose of limiting the scope of claims which might be sought to the present invention. Various changes, modification, and equivalents in addition to those shown or described will become apparent to those skilled in the art and are similarly intended to fall within the spirit and scope of the invention whether or not they presently exist in the following or are later made in amended claims.

We claim:

1. A textile comprising:
a) one or more flexible and elongated charge carrying components wherein each of the one or more charge carrying components includes a first electrode and an oppositely charged second electrode, wherein the first electrode has a charge transport resistance; and
b) one or more flexible and elongated conductive bus bar conduits in contact with the first electrode of at least one of the one or more charge carrying components, the one or more conductive bus bar conduits having a charge transport resistance less than the charge transport resistance of the first electrode.

2. The textile of claim 1 wherein the one or more charge carrying components are photovoltaic components and the first electrode is optically transparent.

3. The textile of claim 2 wherein at least one of the one or more photovoltaic components is a coaxial photovoltaic fiber.

4. The textile of claim 2 comprising a plurality of photovoltaic components and a plurality of conductive bus bar conduits interlaced together.

5. The textile of claim 4 having two opposing planar surfaces wherein the plurality of photovoltaic components are relatively parallel to one another and are interlaced substantially uniformly with the plurality of conductive bus bar conduits that are relatively parallel to one another, wherein the photovoltaic components are roughly perpendicular to the plurality of conductive bus bar conduits.

6. The textile of claim 2 further comprising a first electrode terminal and a second electrode terminal, wherein the first electrode terminal is commonly connected with the first electrode of the one or more photovoltaic components and the second electrode terminal is commonly connected with the second electrode of the one or more photovoltaic components.

7. The textile of claim 6 wherein the first electrode terminal and the second electrode terminal are on opposing planar surfaces of the textile.

8. The textile of claim 2 wherein there are a plurality of photovoltaic components arranged relatively parallel to one another and a plurality of conductive bus bar conduits arranged relatively parallel to one another and in contact with the photovoltaic components to establish multiple unit cells integral with a weave of the textile, wherein each unit cell forms an electrical circuit and wherein the unit cells are electrically connectable to each other through the bus bar conduits of the textile to form an array of circuits.

9. The textile of claim 2 wherein there are a plurality of photovoltaic components arranged relatively parallel to one another and a plurality of conductive bus bar conduits arranged relatively parallel to one another and in contact with the photovoltaic components to establish multiple unit cells integral with a weave of the textile, wherein each unit cell forms an electrical circuit and wherein the unit cells are electrically isolated from one another and connectable to the bus bar to provide isolated sources of electricity from different areas of the textile.

10. The textile of claim 9 wherein the unit cells are isolated from one another by a plurality of insulating gaps extending at least partially along the length of one or more of the plurality of photovoltaic components.

11. The textile of claim 9 wherein the unit cells are isolated from one another by a plurality of non-conducting ribbons woven into the textile.

12. The textile of claim 2 wherein at least one of the one or more conductive bus bar conduits is in the form of a tape.

13. The textile of claim 12 wherein the tape includes an insulating substrate film sandwiched between a top conducting layer and a bottom conducting layer.

14. The textile of claim 2 wherein at least one of the one or more photovoltaic components is a multilayered tape having two edges, wherein the tape includes a flexible insulator integrated along each of the two edges.

15. The textile of claim 14 wherein the tape includes an upper surface and a lower surface, the tape having twin external electrically conductive electrodes on the upper surface and at least one external oppositely charged electrode on the lower surface, a recessed transparent conductive layer between the twin electrodes and an insulating strip along each of the two edges, said twin electrodes in electrical contact with and protruding above the recessed transparent conductive layer to make low resistance electrical contact with the one or more conductive bus bar conduits.

16. The textile of claim 14 wherein the tape includes multiple insulating gaps running from one of the two edges to the other, wherein the tape is arranged with respect to the one or more conductive bus bar conduits so that the insulating gaps electrically isolate segments which are in electrical contact with different bus bar conduits for providing electricity from multiple isolated areas of the textile.

17. A conductive bus bar conduit comprising:
a) an elongated insulating substrate film having a top planar surface and a lower planar surface; and
b) a conducting layer arranged on the top planar surface of the substrate film, said conducting layer configured to provide an electrical contact surface for contact with one or more charge carrying components and to conduct charge with a resistance less than a resistance of the one or more charge carrying components,
wherein the substrate film and conducting layer form a flexible component integrally into a textile.

18. The conductive bus bar conduit of claim 17 further comprising a second conducting layer arranged along the bottom planar surface of the substrate film providing an opposing electrical contact surface, said bottom conducting layer being electrically insulated from the conducting layer on the top planar surface.

19. The conductive bus bar conduit of claim 17 wherein the conducting layer is comprised of metal.

20. The conductive bus bar conduit of claim 17 wherein the insulating substrate film is optically transparent.

21. The conductive bus bar conduit of claim 17 wherein the insulating substrate film is greater in width than the conducting layer, leaving an insulating margin along a length of the conduit on at least one side.

22. The conductive bus bar conduit of claim 17 wherein the insulating substrate film has a curved configuration.

23. A photovoltaic tape for use in a textile having multiple layers comprising:
a) a photovoltaic layer for converting light energy into electricity;
b) one or more electrodes disposed along an upper surface of the tape, said one or more electrodes fixed in a layer above and in electrical contact with the photovoltaic layer; and
c) a lower electrode disposed along a lower surface of the tape, integral with a layer below and in electrical contact with the photovoltaic layer, said lower electrode having an opposite charge with respect to the charge of the electrodes when the photovoltaic tape is exposed to light.

24. The photovoltaic tape of claim 23 wherein the tape has a single electrode and further comprising a flexible edge insulator fixed along at least one edge of the tape for protecting layer insulating margins and isolating electrical charges of the tape layers.

25. The photovoltaic tape of claim 23 wherein the layer below the photovoltaic layer is a conductive polymer backbone.

26. The photovoltaic tape of claim 23 wherein the photovoltaic layer includes an N layer and a P layer.

27. The photovoltaic tape of claim 23 wherein the tape has multiple electrically conductive electrodes along the upper surface of the tape to provide contact points for the transport of charge.

28. The photovoltaic tape of claim 23 further comprising a transparent conductive layer fixed on top and in electrical contact with the photovoltaic layer for protecting the photovoltaic layer while passing light therethrough, wherein the transparent conductive layer is positioned between the upper and lower electrodes.

29. The photovoltaic tape of claim 28 further comprising at least one insulating strip fixed within an edge of the tape for protecting edge margins and electrically isolating charges of the tape layers.

30. The photovoltaic tape of claim 23 further comprising multiple voids in one or more upper most layers of the tape to form insulating gaps, wherein the insulating gaps segment the tape along its length and electrically isolating one segment of the tape from another.

31. The photovoltaic tape of claim 30 wherein a layer below the photovoltaic layer is a conductive polymer.
